(19) United States
(12) Patent Application Publication
(10) Pub. No.: US 2018/0166302 A1
(43) Pub. Date: Jun. 14, 2018

(54) METHOD OF FORMING A NITRIDE SEMICONDUCTOR SUBSTRATE

(71) Applicant: Samsung Electronics Co., Ltd., Suwon-si (KR)

(72) Inventors: Sam-Mook KANG, Hwaseong-si (KR); Mi-Hyun KIM, Seoul (KR); Jun-Youn KIM, Hwaseong-si (KR); Young-Jo TAK, Seongnam-si (KR)

(73) Assignee: Samsung Electronics Co., Ltd., Suwon-si (KR)

(21) Appl. No.: 15/611,279

(22) Filed: Jun. 1, 2017

(30) Foreign Application Priority Data
Dec. 14, 2016 (KR) 10-2016-0170491

(51) Int. Cl. H01L 21/67; H01L 21/02; H01L 21/3065; H01L 21/308

(52) U.S. Cl. CPC H01L 21/67069; H01L 21/02631; H01L 21/02381; H01L 21/02488; H01L 21/3065; H01L 21/3081; H01L 21/02458; H01L 21/0254

(57) ABSTRACT

In a method of forming a nitride semiconductor substrate, a nitride semiconductor substrate may be formed on a silicon substrate. A protection layer may be formed to cover a surface of the nitride semiconductor substrate. The silicon substrate may be removed by an etching process. The protection layer may limit and/or prevent the nitride semiconductor substrate from being etched during the etching process.

### CROSS-REFERENCE TO RELATED APPLICATION

This application claims priority under 35 USC § 119 to Korean Patent Application No. 10-2016-0170491, filed on Dec. 14, 2016 in the Korean Intellectual Property Office (KIPO), the contents of which are herein incorporated by reference in their entirety.

### BACKGROUND

### 1. Field

Some example embodiments relate to a method of forming a nitride substrate.

### 2. Description of Related Art

A nitride semiconductor substrate may be formed on a silicon substrate by a hydride vapor phase epitaxy (HYPE) process. However, when the silicon substrate is removed by an etching process, a surface of the nitride semiconductor substrate may be damaged. Removing the damaged surface may reduce a thickness of the nitride semiconductor substrate. Thus, the HVPE process may be adjusted to form a thicker nitride semiconductor substrate than desired in order to offset thickness lost by removing the damage surface.

### SUMMARY

Some example embodiments provide a method of forming a nitride substrate having improved characteristics.

According to some example embodiments, a method of forming a nitride semiconductor substrate may include forming a preliminary a nitride semiconductor substrate on a silicon substrate, forming a protection layer to cover a surface of the preliminary nitride semiconductor substrate, and removing the silicon substrate using an etching process. The protection layer may limit and/or prevent the nitride semiconductor substrate from being etched during the etching process.

According to some example embodiments, a method of forming a nitride semiconductor substrate may include forming a buffer layer on a silicon substrate, forming a gallium nitride substrate on the buffer layer, forming an etch stop layer including a nitride to cover a surface of the gallium nitride substrate, and removing the silicon substrate using an etching process.

According to example embodiments, a method of forming a nitride semiconductor substrate may include forming a preliminary nitride semiconductor substrate on a stacked structure, forming a protection layer on the preliminary nitride semiconductor substrate, and removing a template substrate included in the stacked structure. The protection layer may cover an upper surface and a side surface of the preliminary nitride semiconductor substrate. The protection layer may be configured to limit the preliminary nitride substrate from being damaged.

In some example embodiments, the protection layer covering the surface of the nitride semiconductor substrate may be formed so as to prevent and/or reduce the surface of the nitride semiconductor substrate from being damaged by the etching gas when the etching process for removing the template substrate under the nitride semiconductor substrate. Thus, there is no need removing the damaged portion, and the nitride semiconductor substrate may not have a thick thickness and the time and cost for manufacturing the nitride semiconductor substrate may decrease.

### BRIEF DESCRIPTION OF THE DRAWINGS

Some example embodiments will be more clearly understood from the following detailed description taken in conjunction with the accompanying drawings.

FIG. 1 is a schematic cross-sectional view illustrating a chamber used for forming a nitride semiconductor substrate in accordance with some example embodiments;

FIGS. 2 to 5 are cross-sectional views illustrating stages of a method of forming a nitride semiconductor substrate; and

FIGS. 6 to 9 are cross-sectional views illustrating stages of a method of forming a nitride semiconductor substrate.

### DETAILED DESCRIPTION

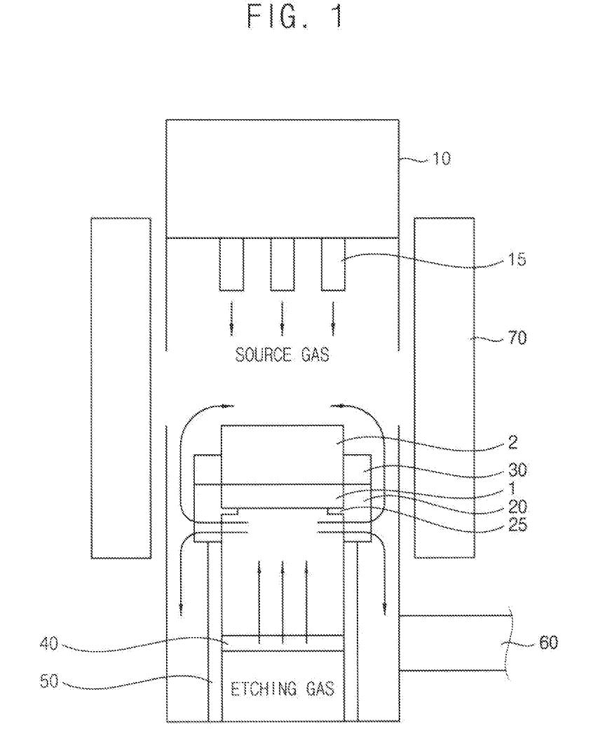

FIG. 1 is a schematic cross-sectional view illustrating a chamber used for forming a nitride semiconductor substrate in accordance with some example embodiments.

Referring to FIG. 1, the chamber may include a source gas supply member 10, a susceptor 20, an etching gas supply member 40, an exhaust member 60, and a heating member 70.

The source gas supply member 10 may be disposed at an upper portion of the chamber, and may provide various source gases for forming a nitride semiconductor substrate 2 onto the susceptor 20 through a port 15. Thus, the nitride semiconductor substrate 2 may be grown on a template substrate 1 loaded onto the susceptor 20. The source gases may be exhausted outside through the exhaust member 60. The exhaust member 60 may include a pipe. The exhaust member 60 may be connected to pump for pumping the source gases outside the chamber. However, inventive concepts are not limited thereto.

The template substrate 1 may be loaded onto the susceptor 20, and may be supported by a tap 25 on the susceptor 20. A cover 30 including, e.g., alumina may be disposed on the susceptor 20.

The etching gas supply member 40 may be disposed at a lower portion of the chamber, and may provide an etching gas for removing the template substrate 1 from the nitride semiconductor substrate 2 toward the susceptor 20. The etching gas member 40 may include a manifold structure with piping connected to etching gas supplies. Flow controllers may regulate the supply of etching gas through the etching gas member 40 to the chamber. However, inventive concepts are not limited thereto.

The etching gas may be provided onto the template substrate 1 from an inner space defined by a partition 50 disposed at a lower portion of the chamber, and may be exhausted via the exhaust member 60. A portion of the etching gas may flow onto the nitride semiconductor substrate 2 on the susceptor 20, and thus a surface of the nitride semiconductor substrate 2 may be partially etched.

The heating member 70 may be disposed at an outside of the chamber, and may heat the chamber during the growth process for the nitride semiconductor substrate 2 and/or the etching process. The heating member 70 may include a heating circuit for providing heat to the chamber through resistive heating. However, inventive concepts are not limited thereto.

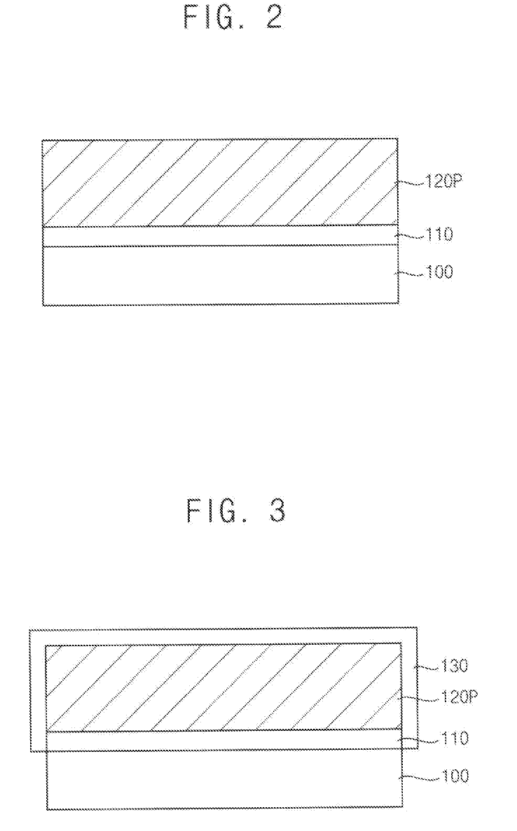

FIGS. 2 to 5 are cross-sectional views illustrating stages of a method of forming a nitride semiconductor substrate.

Referring to FIGS. 1 and 2, a template substrate 100 may be loaded onto the susceptor 20 in the chamber, a buffer layer 110 may be formed on the template substrate 100, and a preliminary nitride semiconductor substrate 120P may be formed on the butler layer 110. The template substrate 100 may include a semiconductor material (e.g., a silicon substrate). The template substrate 100 may have a thickness of, e.g., about 100 μm to about 1,000 μm, and have a diameter of e.g., about 2 inches to about 18 inches. However, inventive concepts are not limited thereto.

The buffer layer 110 may include a material having a low lattice constant similar to those of the template substrate 100 and the nitride semiconductor substrate 120. Thus, cracks may not be generated by tensile strength between the template substrate 100 and the preliminary nitride semiconductor substrate 120P, and melt-back etching may be limited and/or prevented because the template substrate 100 and the nitride semiconductor substrate 120 may not directly contact each other. The template substrate 100 and buffer layer 110 may be referred to as a stacked structure.

The buffer layer 110 may be formed by, e.g., a metal organic chemical vapor deposition (MOCVD) process and a sputtering process. The buffer layer 110 may include, e.g., aluminum nitride, tantalum nitride, titanium nitride, hafnium nitride, aluminum gallium nitride, etc. In some example embodiments, the buffer layer 110 may include a three-layered structure including aluminum nitride/aluminum gallium nitride/gallium nitride.

In some example embodiments, the preliminary nitride semiconductor substrate 120P may be formed by a hydride vapor phase epitaxy (HVPE) process, and may include aluminum nitride, gallium nitride, indium nitride, aluminum gallium nitride, indium gallium nitride, indium aluminum gallium nitride, etc. Hereinafter, for brevity, an example where the nitride semiconductor substrate 120 includes gallium nitride is described.

In some example embodiments, after hydrogen chloride (HCl) and gallium (Ga) may be reacted with each other in the source gas supply member 10 to form gallium chloride (GaCl, GaCl₂, (GaCl₃)₂, GaCl₃), and a nitrogen source gas, for example, ammonia (NH₃) gas together with the gallium chloride may be provided onto the buffer layer 110 on the susceptor 20 via the port 15 to grow a gallium nitride substrate. During the growth process, a silicon source gas may be also provided to dope silicon in the gallium nitride substrate. The growth process of the gallium nitride substrate may be performed at a temperature of about 900° C. to about 1200° C.

The gallium nitride substrate may be formed to have a thickness of about several micrometers to about several millimeters.

Referring to FIGS. 1 and 3, a protection layer 130 may be formed on a surface of the preliminary nitride semiconductor substrate 120P.

The protection layer 130 may be formed of a material having tolerance to a subsequent etching process, e.g., a nitride such as aluminum nitride, silicon nitride, etc.

In some example embodiments, after hydrogen chloride (HCl) and aluminum (Al) may be reacted with each other in the source gas supply member 10 to form aluminum chloride (AlCl, AlCl₂, (AlCl₃)₂, AlCl₃), and a nitrogen source gas, for example, ammonia (NH₃) gas together with the aluminum chloride may be provided onto the nitride semiconductor substrate 120 on the susceptor 20 via the port 15 to form the protection layer 130 including aluminum nitride.

Alternatively, a nitrogen source gas, for example, ammonia (NH₃) gas together with silicon source gas may be provided onto the nitride semiconductor substrate 120 on the susceptor 20 via the port 15 to form the protection layer 130 including silicon nitride.

The process for forming the protection layer 130 may be performed at a temperature of about 500° C. to about 1400° C.

The protection layer 130 may cover at least an upper surface of the preliminary nitride semiconductor substrate 120P, and partially or entirely cover a sidewall of the preliminary nitride semiconductor substrate 120P. In some cases, the protection layer 130 may cover a sidewall of the buffer layer 110 under the preliminary nitride semiconductor substrate 120P. The protection layer 130 may have a thickness of, e.g., about several nanometers to about hundreds of micrometers.

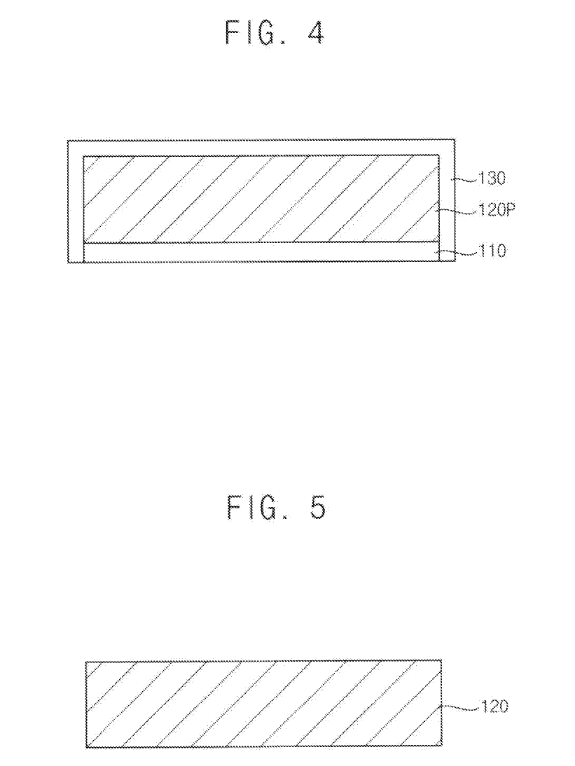

Referring to FIGS. 1 and 4, the template substrate 100 under the preliminary nitride semiconductor substrate 120P may be removed.

In some example embodiments, the template substrate 100 may be removed by a dry etching process. That is, hydrogen chloride (HCl) or a chlorine-based etching gas, e.g., chlorine (Cl₂) gas may be provided onto the susceptor 20 from the etching gas supply member 40 to remove the template substrate 100 loaded onto the susceptor 20.

The chlorine-based etching gas may be provided from the inner space defined by the partition 50 toward the susceptor 20, and may be exhausted by the exhaust member 60. A portion of the chlorine-based etching gas may flow onto the surface of the preliminary nitride semiconductor substrate 120P on the susceptor 20. However, the surface of the preliminary nitride semiconductor substrate 120P may be covered by the protection layer 130 including a nitride having a strong tolerance to the chlorine-based etching gas, e.g., aluminum nitride or silicon nitride, and thus may not be damaged or etched by the etching process.

The etching process may be performed at a temperature of about 500° C. to about 1400° C.

Referring to FIGS. 1 and 5, the buffer layer 110 and the protection layer 130 may be removed to form an independent nitride semiconductor substrate 120 from the preliminary nitride semiconductor substrate 120P.

The buffer layer 110 and the protection layer 130 may be removed by grinding, lapping and/or polishing. Alternatively, the buffer layer 110 may be also removed in the etching process of the template substrate 100.

As illustrated above, the protection layer 130 covering the surface of the preliminary nitride semiconductor substrate 120P may be formed so as to prevent or reduce the surface of the preliminary nitride semiconductor substrate 120P from being damaged by the etching gas when the etching process for removing the template substrate 100 under the nitride semiconductor substrate 120. Thus, there is no need removing the damaged portion, the time and cost for manufacturing the nitride semiconductor substrate 120 may decrease because a thickness reduction of the preliminary nitride semiconductor substrate 120P from removing the damaged portion may be avoided and/or reduced.

The protection layer 130 may limit and/or prevent the preliminary nitride semiconductor substrate 120P from being etched during the etching process, and may be also referred to as an etch stop layer.

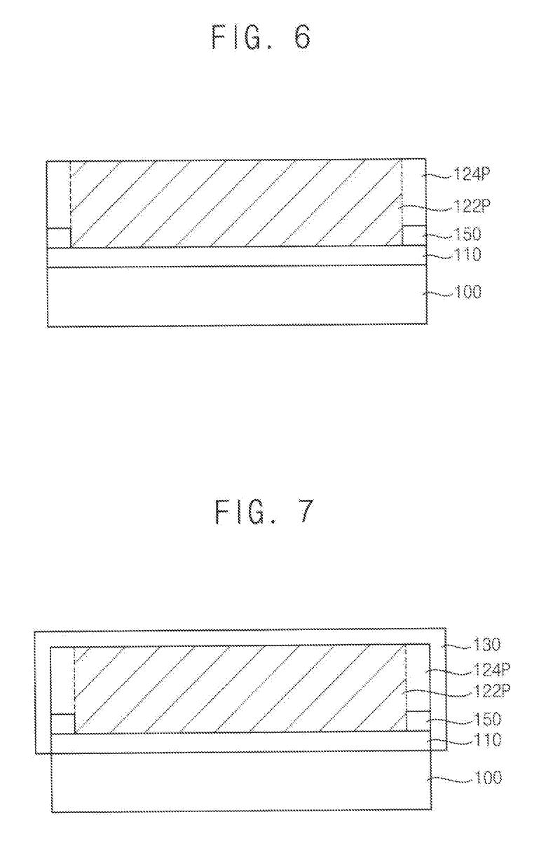

FIGS. 6 to 9 are cross-sectional views illustrating stages of a method of forming a nitride semiconductor substrate. This method may include processes substantially the same as or similar to those illustrated with reference to FIGS. 1 to 5. Like reference numerals refer to like elements, and detailed descriptions thereon may be omitted below in the interest of brevity.

Referring to FIG. 6, a buffer layer 110 may be formed on the temperature substrate 100, an insulation pattern 150 may be formed on the buffer layer 110, and first and second preliminary nitride semiconductor substrates 122P and 124P may be formed on the buffer layer 110 and the insulation pattern 150. The first and second preliminary nitride semiconductor substrates 122P and 124P may be referred to as first and second portions 122P and 124P of a preliminary nitride semiconductor substrate, respectively.

The insulation pattern 150 may be formed by forming an insulation layer through a chemical vapor deposition (CVD) process or a sputtering process, and patterning the insulation layer through an etching process. The insulation layer may be formed of, e.g., silicon oxide, silicon nitride, etc.

In some example embodiments, the insulation pattern 150 may be formed on an edge upper surface of the butler layer 110, and thus crack at an upper portion of the buffer layer 110 may be covered by the insulation pattern 150. The insulation pattern 150 may be formed to have a thickness of, e.g., about several nanometers to about dozens of micrometers.

The first and second preliminary nitride semiconductor substrates 122P and 124P may be formed by a HVPE process, and a single crystalline gallium nitride substrate and a poly-crystalline gallium nitride substrate may be formed on the buffer layer 110 and the insulation pattern 150, respectively. The first preliminary nitride semiconductor substrate 122P may be single crystalline gallium nitride. The second preliminary nitride semiconductor substrate 124P may be a poly-crystalline gallium nitride substrate. The first and second preliminary nitride semiconductor substrates 122P and 124P may be formed of different materials.

Referring to FIG. 7, processes substantially the same as or similar to those illustrated with reference to FIGS. 1 and 3 may be performed to form the protection layer 130 on surfaces of the first and second preliminary nitride semiconductor substrates 122P and 124P.

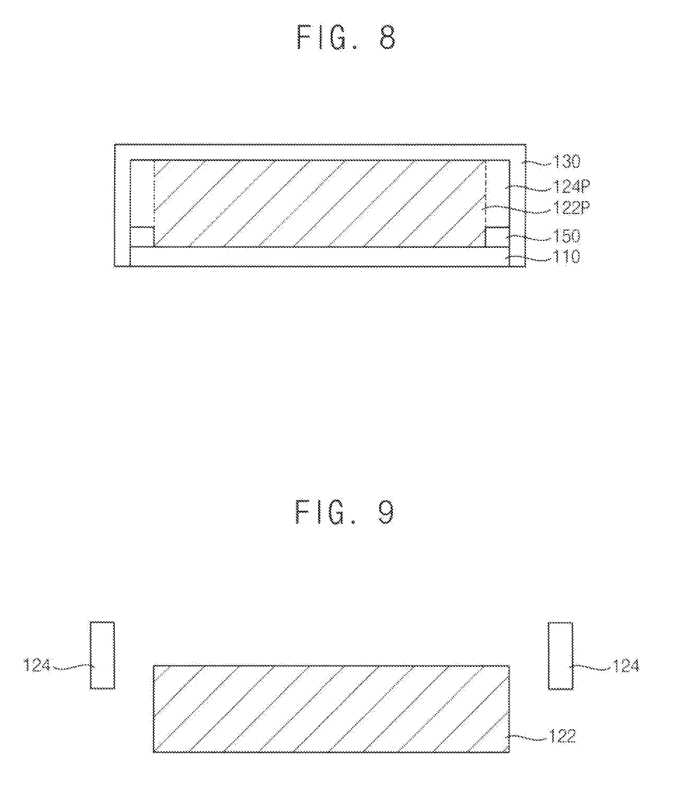

Referring to FIG. 8, processes substantially the same as or similar to those illustrated with reference to FIGS. 1 and 4 may be performed to remove the template substrate 100 under the first and second preliminary nitride semiconductor substrates 122P and 124P.

During the removal process of the template substrate 100, a portion of the etching gas may flow onto the surfaces of the first and second preliminary nitride semiconductor substrates 122P and 124P; however, the surfaces of the first and second preliminary nitride semiconductor substrates 122P and 124P may be protected by the protection layer 130 including a material having strong tolerance to the etching gas.

Referring to FIG. 9, processes substantially the same as or similar to those illustrated with reference to FIGS. 1 and 5 may be performed to complete the nitride semiconductor substrate.

That is, the buffer layer 110 and the protection layer 130 may be removed by, e.g., a grinding process, and the insulation pattern 150 may be also removed. The first and second preliminary nitride semiconductor substrates 122P and 124P may be divided from each other, for example, by a laser dicing process or a water-jet cutting process, and thus the first nitride semiconductor substrate 122 including a single crystalline gallium nitride may be formed from the first preliminary nitride semiconductor substrate 122P, and a second nitride semiconductor substrate 124 may be formed from the second preliminary nitride semiconductor substrate 124P.

Although a few example embodiments have been described, the example embodiments described herein are for illustrative purposes, not for limiting purposes. Those skilled in the art will readily appreciate that many modifications are possible in example embodiments without materially departing from the novel teachings and effects of present inventive concepts. Accordingly, all such modifications are intended to be included within the scope of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a nitride semiconductor substrate, the method comprising:
forming a preliminary nitride semiconductor substrate on a silicon substrate;
forming a protection layer to cover a surface of the preliminary nitride semiconductor substrate, the protection layer being configured to limit the preliminary nitride semiconductor substrate from being etched during an etching process; and
removing the silicon substrate using the etching process.

2. The method of claim 1, wherein
the removing the silicon substrate includes using a chlorine-based etching gas during the etching process, and
the protection layer includes a nitride.

3. The method of claim 2, wherein
the chlorine-based etching gas includes at least one of hydrogen chloride (HCl) gas or chlorine (Cl₂) gas, and
the protection layer includes at least one of silicon nitride or aluminum nitride.

4. The method of claim 1, wherein the preliminary nitride semiconductor substrate includes at least one of gallium nitride, indium nitride, aluminum gallium nitride, indium gallium nitride, and indium aluminum gallium nitride.

5. The method of claim 1, wherein the forming the preliminary nitride semiconductor substrate includes performing a hydride vapor phase epitaxy (HVPE) process.

6. The method of claim 1, further comprising:
forming a buffer layer on the silicon substrate before the forming the preliminary nitride semiconductor substrate on the silicon substrate, wherein
the forming the preliminary nitride semiconductor substrate on the silicon substrate includes forming the preliminary nitride semiconductor substrate on the buffer layer.

7. The method of claim 6, wherein the buffer layer includes at least one of aluminum nitride, tantalum nitride, titanium nitride, hafnium nitride, or aluminum gallium nitride.

8. The method of claim 6, further comprising:
forming an insulation pattern on the buffer layer.

9. The method of claim 8, wherein
the preliminary nitride semiconductor substrate includes a first portion and a second portion,
the forming the preliminary nitride semiconductor substrate includes forming the first portion on the buffer layer and forming the second portion on the insulation pattern, and
the method further includes dividing the first portion and the second portion from each other after the removing the silicon substrate.

10. A method of forming a nitride semiconductor substrate, the method comprising:
forming a buffer layer on a silicon substrate;
forming a gallium nitride substrate on the buffer layer;
forming an etch stop layer to cover a surface of the gallium nitride substrate, the etch stop layer including a nitride; and
removing the silicon substrate using an etching process.

11. The method of claim 10, wherein
the removing the silicon substrate includes using at least one of hydrogen chloride (HCl) gas or chlorine (Cl₂) gas in the etching process, and
the etch stop layer includes at least one of silicon nitride or aluminum nitride.

12. The method of claim 10, wherein the forming the gallium nitride substrate includes forming the gallium nitride substrate using an HVPE process.

13. The method of claim 10, wherein the buffer layer includes at least one of aluminum nitride, tantalum nitride, titanium nitride, hafnium nitride, or aluminum gallium nitride.

14. The method of claim 10, further comprising:
forming an insulation pattern on the buffer layer.

15. The method of claim 14, wherein
the gallium nitride substrate includes a first portion and a second portion,
the forming the gallium nitride substrate includes forming the first portion on the buffer layer and forming the second portion on the insulation pattern, and
and the method further includes dividing the first portion and the second portion from each other after the removing the silicon substrate.

16. A method of forming a nitride semiconductor substrate, the method comprising:
forming a preliminary nitride semiconductor substrate on a stacked structure, the stacked structure including a template substrate;
forming a protection layer on the preliminary nitride semiconductor substrate, the protection layer covering an upper surface and a side surface of the preliminary nitride semiconductor substrate, the protection layer being configured to limit the preliminary nitride semiconductor substrate from being damaged; and
removing the template substrate.

17. The method of claim 16, wherein
the stacked structure includes a buffer layer on the template substrate, and
the forming the preliminary nitride semiconductor substrate includes forming the preliminary nitride semiconductor substrate on the buffer layer.

18. The method of claim 16, wherein
the removing the template substrate includes using a chlorine-based etching gas during an etching process, and
the protection layer includes a nitride that is a different material than the preliminary nitride semiconductor substrate.

19. The method of claim 16, wherein the forming the preliminary nitride semiconductor substrate includes performing a hydride vapor phase epitaxy (HVPE) process.

20. The method of claim 16, further comprising:
removing the protection layer, wherein
the template substrate is a silicon substrate.
